(19) United States
(12) Patent Application Publication
(10) Pub. No.: US 2008/0284457 A1
(43) Pub. Date: Nov. 20, 2008

(54) METHOD AND APPARATUS FOR CONTROL OF A POSITIONING DEVICE

(75) Inventors: Ulf HACKIUS, Dresden (DE); Frank FEHRMANN, Priestewitz OT Basslitz (DE); Juliane BUSCH, Dresden (DE); Ralf KELLER, Dresden (DE)

Correspondence Address: HESLIN ROTHENBERG FARLEY & MESITI PC, 5 COLUMBIA CIRCLE, ALBANY, NY, 12203, US

(73) Assignee: SUSS MicroTec Test Systems GmbH, Thiendorf OT Sacka (DE)

(21) Appl. No.: 12/111,222

(22) Filed: Apr. 29, 2008

(30) Foreign Application Priority Data
Apr. 30, 2007 (DE) 10 2007 020 643.9

(51) Int. Cl. G01R 31/26; H01L 21/67

(52) U.S. Cl. 324/758; 414/754; 414/800

(57) ABSTRACT

In a device and a method for positioning an object, a drive of a movement device is controlled. To this end, a visual joystick is actuated, as a result of which a moveable actuator is moved, at least linearly by means of a display of a control unit of the movement device, into a position, in which a direction of movement, which can be implemented with the drive, is displayed symbolically. The drive for the movement of the object in the displayed direction of movement is initiated by means of a switching function of the actuator.

### CROSS REFERENCE TO RELATED APPLICATIONS

This application claims priority of German application No.: 10 2007 020 643.9 filed on Apr. 30, 2007, the entire disclosure of this application being hereby incorporated herein by reference.

### BACKGROUND ART

The invention relates to a method for positioning a semiconductor substrate in relation to test tips. In this case a drive of a movement device is controlled with the assistance of a menu. To this end an actuator, which can be moved at least linearly over a menu area of a display of a control unit of the movement device, moves into a position, in which a direction of movement, which can be implemented with the drive, is displayed symbolically. Then the drive for the movement of the semiconductor substrate or the test tips (hereinafter referred to in general as the object) in the displayed direction of movement is initiated by means of a switching function of the actuator. The invention also relates to a device for carrying out the positioning method.

Such movement devices are used in a variety of applications in order to position two objects in relation to one another. For example, it is necessary for testing semiconductor substrates in test stations, which are generally known as probers, to position a test tip for tapping or feeding measurement signals or to position optical devices for observation purposes in relation to a semiconductor substrate. In this case, both the movement of just one of the two objects or both objects is necessary. The movement itself may be the approach of positions, which are to be set individually, or also the following of a sequence of positions. This listing represents examples of movement devices, to which the invention relates, and is not intended to be restrictive in any way.

In the probers the semiconductor substrates that are to be tested are arranged on a first holding device—the chuck. The chuck is connected to a first movement device. Such movement devices often comprise X-Y cross tables, which make possible the positioning of the chuck and, thus, the test objects with the high degree of accuracy that is necessary because of the constantly increasing scaling in the manufacture of semiconductors.

The test tips are held by an additional holding device, which is connected to another movement device. This movement device has, inter alia, fewer degrees of freedom or serves only to overcome shorter distances than the first movement device. Often the positioning is also executed in two steps—a coarse and a fine positioning, each of which can be accomplished with the two movement devices or, in addition, by both of them together.

The positioning and also the testing is often carried out by means of optical devices, which must also be positioned. Even the positioning of the optical devices can be carried out by means of the inventive method and the inventive device as an alternative or in addition to the positioning of the test object and/or the test tips.

Whereas both the two holding devices and the optical devices can be manipulated in up to three directions of movement, there ensues also, in addition, an angular orientation between the test object and the test tips, in order for a larger number of test tips to make contact simultaneously with the contact points of the test object, these contact points being often very small.

For the positioning of the objects a variety of motors are used—for example, stepping motors or direct current motors, which differ with respect to the important components for approaching the position—the speed and the resolution between two positions. The motors that are used for carrying out the individual movements usually exhibit a control with a microprocessor. These motors are operated by means of a control unit, usually a computer; and the operational control is often menu assisted.

For example, in the case of operating a computer it is generally known that the selection and activation of the menu assisted functions are carried out with a cursor, trackball, touch screen or joystick in that individual function switches, shown on a display, are selected and switched with the cursor or one of the other auxiliary means. In this respect the control of a movement device for positioning an object presents the problem that not only the direction of a movement but also the speed or the resolution cannot be varied or can be varied only in discrete steps with the selection of a function switch.

### BRIEF SUMMARY OF INVENTION

Therefore, the object of the present invention is to provide a movement device for positioning an object, in particular for use in probers, and a method for positioning. Both the device and the method make possible a menu assisted control with continuously adjustable movement parameters while simultaneously guaranteeing the necessary accuracy of the positioning.

The described movement device enables a totally menu controlled operator control of a movement device for positioning an object, in which both the direction of movement and the speed of the movement can be controlled continuously and directly by means of the menu.

This menu-controlled operator control can be applied to a plurality of parallel or series connected movement devices, so that complicated movement sequences, which are to be executed by means of a plurality of movement devices, are controlled by means of a menu and can also be continuously controlled with respect to direction and speed. In addition, this menu controlled operator control can also be retrofitted for movement devices of existing systems.

The menu guided speed control permits the speed to vary as a function of the remaining distance for each positioning event and as a function of the resolution of the minimal distance to be overcome with a control step.

For an optimal adjustment of the speed and the direction of the movement to the real situation and the remaining distance to the end position, the symbolic display of the direction of movement and the speed can be combined with a display of the real position of the object with respect to its end position. In this way it is possible to make corrections during the running movement or to carry out other than straight line movement sequences.

The device and the method for positioning are explained below with reference to the positioning of the chuck. The use for one of the other movement devices or a movement device in one of the aforementioned other applications shall be explained in an analogous manner.

### BRIEF DESCRIPTION OF THE DRAWING FIGURES

FIG. 1 depicts a menu of a control unit of a movement device for operating the control unit.

FIG. 2 depicts a visual joystick having one direction of movement or two directions of movement, each of which can be traversed with a movement device, against the background of a real representation of a semiconductor substrate.

FIG. 3 depicts a visual joystick having one direction of movement or two directions of movement, each of which can be traversed with a movement device, against the background of a schematic representation of a semiconductor substrate.

FIG. 4 depicts a prober for testing semiconductor substrates with movement devices, according to FIG. 1.

### DETAILED DESCRIPTION

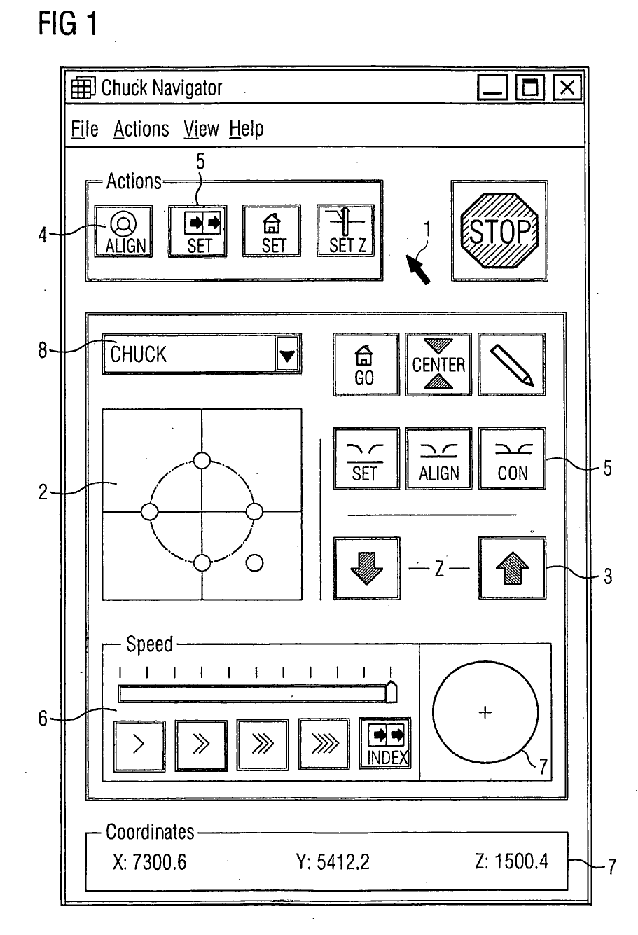

FIG. 1 depicts the menu of a control unit 1 of the movement device of the invention. The menu is operated with a cursor, as the actuator 1, in a manner that is generally known from the use of a personal computer with a computer mouse (not illustrated) or a trackball or the like. For the sake of a better overview the description shall focus below on the use of the actuator 1 with a computer mouse.

The menu comprises a switch-over switch 8, with which the control can be switched over and applied to another movement device of a prober. In this case the movement device is to be used to operate the control unit. The selection takes place in a menu, according to FIG. 1, using a pull down menu. In an alternative design the selection can also be carried out with a plurality of several switches. The activation of these switches—by means, for example, of a computer mouse—connects the control unit to the selected movement device.

If the switch over is from one to the other movement device, then the functions that are described below are executed in the same way with the other movement device. Therefore, it is possible that not every one of the illustrated function switches 2-6 can be applied to each movement device, which is to be selected. For example, an angular orientation or a movement in the Z direction or the activation of programmed movement sequences can be executed only with certain movement devices. In the drawing in FIG. 1 the movement device of the chuck of a prober is selected with the switch-over switch 8, so that the function switches 2-6 that are described below are applied to this movement device and are described with respect to this movement device.

Furthermore, the menu comprises a plurality of function switches 2-6, which are illustrated by rectangular symbols, which are shown in FIG. 1 and which show a pictogram-like rendering of the function that can be activated with the function switch 2-6. These function switches 2-6 can be approached with the actuator 1 and operated with a mouse click while the actuator 1 is positioned on this function switch. A variety of functions, which can be implemented with a movement device, are activated with the use of various function switches 2-6.

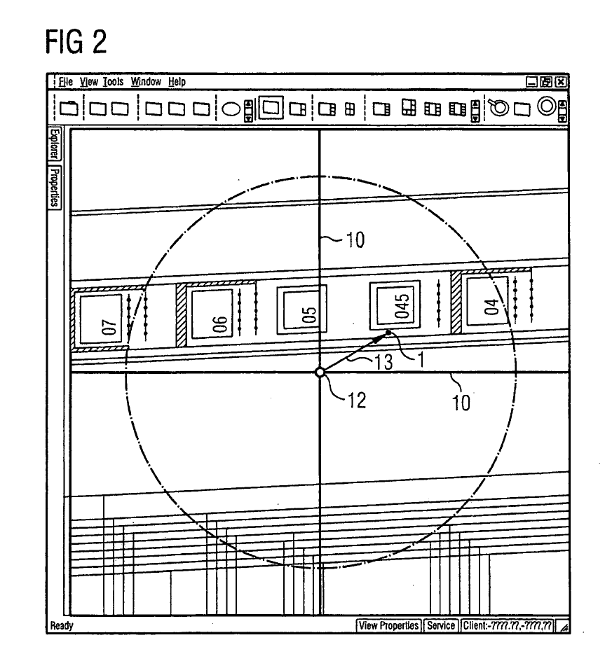

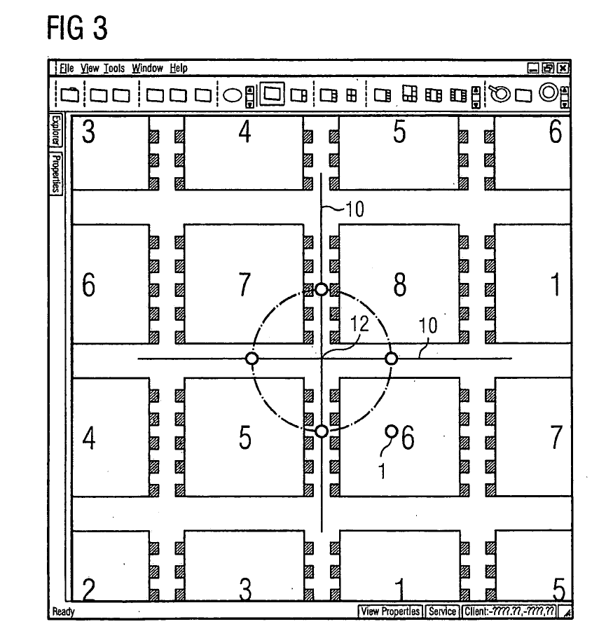

A first function switch 2 activates a visual joystick (FIG. 2, FIG. 3), with which the positioning direction and the positioning speed of the movement devices of the chuck can be controlled.

The movement devices that were selected here with the switch-over switch 8 represent examples. Again the activation is performed with a mouse click, whereupon a drawing, according to FIG. 2 or FIG. 3, is displayed. Whether a visual joystick, according to FIG. 2 or according to FIG. 3, is displayed is possible, for example, by means of an additional switch to make a pre-selection in the menu.

In the illustrated embodiment additional function switches activate an infeed 3 in the Z direction between a test object on a chuck and test tips as well as their removal from one another in the opposite direction. Switching can cause the Z drive of the chuck to be activated, either as long as the switch remains depressed by means of the computer mouse or, as an alternative, by a first up to a second switching operation. Other functions are possible as a function of the configuration of the movement device to be controlled.

In another embodiment, by switching this function switch 3 a visual joystick can be activated for a movement only in the Z direction, so that the display is switched over to the visual joystick with the symbolic direction and speed display, according to FIG. 2 or FIG. 3, or the result is a suitable modification of said display. As described below, relevant in the visual joystick, according to FIG. 2 or FIG. 3 is the display of one of the two directions, shown by the axes, preferably the perpendicular direction, as well as the speed for the infeed.

Other function switches 4 are used for the angular orientation of the chuck in relation to the test tips. As described above for the function switch 3 for the infeed in the Z direction, switching the function switch 4 causes the activation of a rotational device of the chuck either as long as the switch remains depressed or until it is depressed again.

For these movements in the Z direction or rotational movements the distance and/or the angle that must be overcome is/are often known, so that for these movements or also for other known movements the sequences can be listed in a memory of the control unit, and these sequences can be carried out by switching a corresponding function switch 5 for the programmed movement sequences. These movement sequences can also take place in the X-Y plane or be composed of a plurality of individual steps—for example, in order to approach specifically known positions or to perform a rasterization. A known movement in the Z direction constitutes, for example, producing a contact between the test object and the test tips by moving the chuck or, as an alternative, by moving the test tips. In such programming operations the switching operations of the switch-over switch can also be implemented.

In another embodiment one factor can be applied to the individual speeds or to all speeds in that a multiplier is selected for a speed factor 6 by means of a function switch. Then the control unit converts this multiplier using, for example, an amplification factor in order to activate the drive. In the illustrated embodiment the speed factor may be set by means of the slide switch so as to be continuous or by means of other function switches so as to be discrete.

In addition, the menu comprises a display of position 7 of a reference point of the chuck—for example, its center point in the bearing surface in a prober-related Cartesian coordinate system.

In FIGS. 2 and 3 the operating mode of the visual joystick is presented in detail. The display of the control unit changes to the symbolic display of one direction of movement or two directions of movement, each of which can be implemented with the movement device, as soon as the visual joystick is activated or under some circumstances when, as described above, a Z movement is carried out by means of the function switch 3, which is provided for this purpose. The symbolic display is activated, according to FIG. 2 or 3, by a switching function with the actuator 1 to the function switch 2 of the visual joystick.

FIG. 2 shows two directions of movement—the X and Y direction —, which can be implemented with a chuck drive. Both directions define jointly a coordinate system with a coordinate origin 12. Whereas the X and Y directions represent the two directions of movement, which can be traversed with an X-Y cross table, the coordinate origin 12 represents the starting point of a movement. The coordinate origin 12 tracks the movement upon completion of a continuous sequence of movement steps. In this way the coordinate origin 12 always shows the real position of the chuck at the beginning of each movement sequence or substep thereof. In FIG. 2 the real representation of the semiconductor substrate to be tested is not oriented at an angle to the X and Y axes—that is, to both directions of movement. Nevertheless, a positioning is possible on the basis of the real representation. As an alternative, on the basis of an angle, to be determined from the representation, an angular orientation can be carried out with the corresponding function switch of the menu in FIG. 1.

In the coordinate system the actuator 1, depicted as a filled in white dot, must be moved as in a visual joystick. The visual joystick acts together with the drive comparable to a physical joystick. For this purpose the locations of the visual joystick that are set as the end point of an actuator movement or partial movement, and a switching function, which is carried out with the actuator 1 in the respective location, serve to generate a control signal that is suitable for the control of the chuck drive.

In order to approach a chuck position inside the X-Y plane, which is defined by the surface of the chuck, the joystick in the symbolic display 10 of the X and Y direction of movement is pulled from a first location to a second location in the coordinate system. In order to improve the representation, a vector 13 is drawn in FIG. 2. This vector symbolizes the movement of the visual joystick. In one embodiment this joystick may be a part of the display—for example, in order to show the direction, in which the actuator 1 is displaced.

Whereas the first location—the starting point of the vector 13—is the starting point of a positioning sequence and, thus, can be the end point of a preceding subsection of a complicated positioning sequence, the second location—the end point of the vector 13—corresponds to the end point of the positioning sequence and can be programmed based on the known positions to be set on the test object or is to be determined visually by means of a true-to-scale real (FIG. 2) or schematic drawing (FIG. 3) of the test object in the symbolic display. With the aid of the real or schematic drawing of the test object in the symbolic display or at least with a geometric reference to the symbolic display the movement of the object can be shown continuously. In this way a continuous movement, which is composed of a plurality of individual movements, can be realized in a simple way.

Following the movement of the actuator 1 in the symbolic display 10, a switching function can be used to perform, for example, in the embodiment, a switching function, which can be implemented generally with a computer mouse, in the second location. Thus, the control unit generates a control signal, which is transmitted to the drive of the chuck.

The drive in the X and Y direction is controlled by means of the movement of the actuator 1 so that the individual movements in the X and Y direction are mixed to some extent and produce a resulting positioning movement that corresponds to the direction of the vector 13.

In the case of an X-Y cross table and a Cartesian coordinate system, the movements in both directions of movement must be determined in a simple way from the X and Y coordinates, provided that the reference point of the coordinate system is continuously in conformity with the first location and, thus, with the starting point of a new movement. Therefore, under the coordinate system and with the drawing of the test object in the coordinate system the test object is moved along under the observation position.

The control signal, which is transmitted to the drive, controls not only the direction but also the speed of the movement by means of the movement of the actuator 1 in the symbolic display 10. The amount of the vector 13—that is, its length—serves as a measure for the speed. This measure is applied to a defined speed of the drive. In order to be able to use the amount of the distance for each additional movement as a factor for the drive speed, the coordinate system always mimics the movement, so that the end point of a movement is the coordinate origin 12 for the next movement.

Prior to the movement or between two substeps, the determination of the speed by means of one of the function switches 6, shown in FIG. 1, for a speed factor can be based on an additional factor. In order to overcome longer distances or for coarse positioning, this factor may be greater than 1; for a deceleration of the movement—for example, for fine positioning, this factor may be less than 1.

In another embodiment it is possible, as an alternative, to link together (instead of a proportional relationship between the amount of the vector 13 and the speed) both values by means of a function that can be selected without restriction. It is even possible to store a logarithmic function. This relationship between the amount of the vector and the speed can be programmed in the control unit.

In a comparable manner, the visual joystick can also be used to carry out a movement in only direction—for example, in the Z direction, as described above. In this case the direction is set by shifting the actuator 1 away from the coordinate origin 12 into one of the halves of a symbolic display 10 of the Z direction. If the actuator 1 is pulled into the upper half of the symbolic display 10, a movement occurs in the positive Z direction. If the vector 13 points into the bottom half, then the chuck moves in the negative Z direction. Similarly this can be applied to the X or Y direction with suitable programming of the control unit.

For the symbolic display 10 of the direction of movement against the real background of the test object, as shown in FIG. 2, it may be necessary, for example, during the movement in the Z direction, to provide a variety of real views, to which a switch over can be made by actuating a function switch 2-6.

Moreover, the described functions of the visual joystick can also be applied to a different drive, which is connected to the control unit and, thus, to the visual joystick, —that is, can be applied to its directions of movement and implementable speeds. For example, the amount and the speed of the angular orientation can be controlled in a simple way by means of the visual joystick, if the coordinate system is defined as a polar coordinate system, and the speed is controlled by changing the radius and the angle to be rotated is controlled by changing the angle after adjusting the location of the actuator in relation to the preceding actuator position. In this case, however, the coordinate origin does not mimic, as described above, the movement, in order to be able to determine a change in angle.

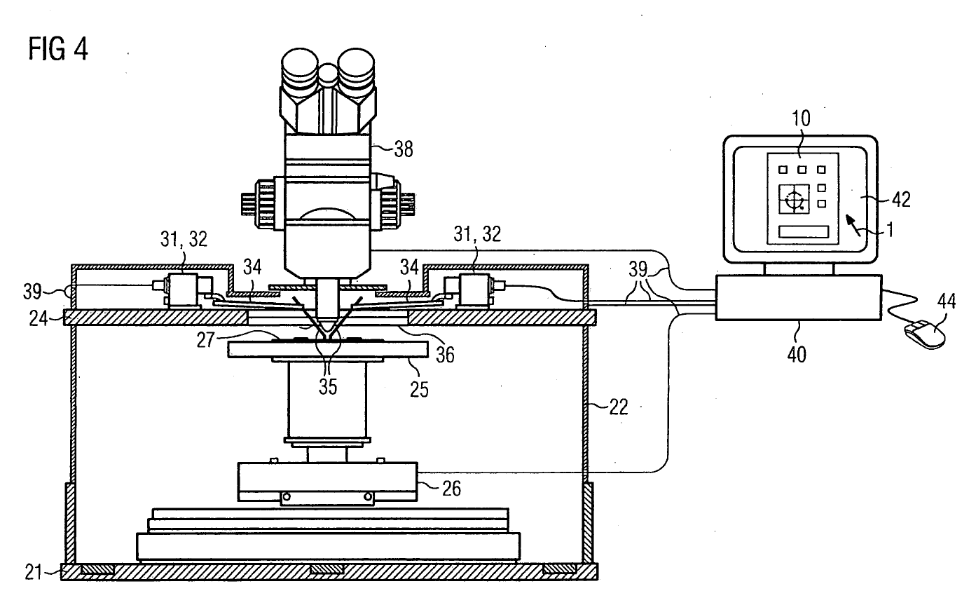

FIG. 4 is a schematic drawing of a prober for testing semiconductor substrates.

The prober exhibits a chuck 25, on which a semiconductor substrate 27 can be placed. The chuck 25 comprises a chuck movement device 26, with which the chuck 25 is to be moved in the X, Y and Z direction and can be rotated about the Z axis in a certain angular range. The chuck 25, including its movement device 26, is surrounded by a housing wall 22 on the bottom side and on the lateral side.

A probe holder plate 24, which seals the housing wall 22 at the top, is disposed opposite the chuck 25 and simultaneously the semiconductor substrate 27. Probes 34 are mounted on the probe holder plate 24 by means of probe holders—so-called probe heads 31. These probes make electrical contact with the semiconductor substrate 27 through a central aperture 36 in the probe holder plate 24. Each probe head 31 holds one probe or a plurality of probes 34 and comprises a dedicated movement device—a probe movement device 32 with an electrically operated drive. By using the probe movement device 32, each probe 34 or group of probes can be positioned in the direction of the semiconductor substrate 27—that is, in the Z direction. The probe heads 31 are also surrounded by housing walls 22.

During the movement of the chuck 25 and the contact between the semiconductor substrate 27 and the probe tips 35, the semiconductor substrate 27 or at least a detail thereof is observed with a microscope unit 38. To this end, the housing wall 22 exhibits a viewing window through the central aperture 36 of the probe holder plate 24. The microscope unit 38 is arranged above this viewing window. The microscope unit 38 comprises a microscope movement device (not illustrated), which also exhibits an electrically operated drive.

The movement devices 26, 32 of the chuck, the probe heads and the microscope unit are connected to a control unit 40—in the embodiment a computer—by means of dedicated connectors 39, as an alternative also without a cable. With the use of the computer 40 the drives of all movement devices are activated and controlled in the above described manner. To this end, the computer 40 is connected to a display 42, in order to show the symbolic display 10, according to FIG. 1, or the visual joystick, according to FIG. 2 or FIG. 3, as well as connected to a computer mouse 44, in order to operate the actuator on the display 42. The parameters, which are required to control all of the movement devices, the functions, the calibrations or the like, as well as the above described speed factors or speed functions are stored in the control unit 40.

1. Movement device for positioning a semiconductor substrate in relation to test tips has a first drive and a control unit of the movement device, the control unit comprising a display having a symbolic display of at least one direction of movement, that can be implemented with the drive, and an actuator, adapted to be moved at least linearly in the symbolic display and with which drive for a movement of the semiconductor substrate or the test tips in the displayed direction of movement can be initiated, wherein speed, with which the drive moves the substrate or test tips is controlled by distance of the actuator from a reference point in the symbolic display.

2. Movement device, as claimed in claim 1, wherein two directions of movement, which can be implemented with the drive, define a coordinate system, depicted in the symbolic display; a starting point of the positioning movement is represented as a first location; and an end point is represented as a second location in the coordinate system; and positioning movement of the substrate or test tips, resulting from both directions of movement, is controlled by a direction, defined by a straight line, connecting two points, in the coordinate system.

3. Movement device, as claimed in claim 1, further comprising an additional drive; wherein the symbolic display is adapted to be switched over to the additional drive; and speed and/or positioning direction of the additional drive is controlled by the actuator and the symbolic display.

4. Movement device, as claimed in any claim 1, further comprising an additional drive; and wherein the display of the control unit comprises an additional symbolic display for controlling speed and/or positioning direction of the additional drive by an actuator in the additional symbolic display.

5. Movement device, as claimed in claim 1, wherein movement, implemented by the movement device, is depicted on the display based on the symbolic display.

6. Movement device, as claimed in claim 1, wherein the display shows a symbol of at least one additional function of the movement device, selected and operated with the actuator.

7. Movement device, as claimed in claim 1, wherein the movement device is assigned at least one additional movement device, the control unit is connected to the at least one additional movement device, and is applied by choice to the movement device or the at least one additional movement device.

8. Prober for testing semiconductor substrates, comprising:
a holding device for holding a semiconductor substrate,
an additional holding device for holding test tips, which serve to apply test signals to the substrate and/or to tap them, and
a movement device, as claimed in claim 1, for positioning the substrate relative to the test tips.

9. Prober for testing semiconductor substrates, comprising:
a holding device for holding a semiconductor substrate,
an additional holding device for holding test tips, which serve to apply test signals to the substrate and/or to tap them,
a first movement device, as claimed in claim 7, for positioning the substrate relative to the test tips, and
a second movement device, the control unit of the first movement device being connected to the second movement device and being applied by choice to one of the first and second movement devices.

10. Method for positioning a semiconductor substrate relative to test tips, wherein a drive of a movement device being controlled by an actuator, which can be moved at least linearly over a display of a control unit of the movement device, is moved to a location on the display; and drive for movement of the semiconductor substrate or the test tips in a displayed direction of movement is initiated by a switching function of the actuator, the display shows a symbolic display of a direction of movement, which can be realized with the drive; the actuator in the symbolic display is moved from a first location to a second location; and the first and second locations are determined; said switching function is carried out at the second location in the symbolic display; and thereupon a control signal is generated and transmitted to the drive, as a consequence of which the drive is driven at a speed proportional to a distance between the first and second locations.

11. Positioning method, as claimed in claim 10, wherein the actuator in a coordinate system, defined by two directions of movement, which can be implemented with the drive, is moved from a first location to a second location; and the execution of the switching function of the actuator in the second location generates a control signal transmitted to the drive and which brings about not only control of the speed but also control of the drive in the two directions of movement, so that a direction of a resulting positioning movement of the substrate or test tips corresponds to direction defined by a straight line, connecting two locations, in the coordinate system.

12. Positioning method, as claimed in claim 10, wherein real movement of the substrate or test tips is shown on the display based on the symbolic display.

13. Positioning method, as claimed in claim 10, wherein by actuating a switch-over switch, control by change in location of the actuator in the symbolic display is applied to an additional drive of the movement device.

14. Method for testing semiconductor substrates, comprising:
positioning a semiconductor substrate, held on a bearing surface of a first holding device, in a plane, defined by the bearing surface, by the positioning method, as claimed in claim 10,
wherein the positioning ensues in relation to test tips, which are held in an additional holding device,
making contact with the semiconductor substrate through the test tips by an infeed movement between the test tips and the semiconductor substrate, and
testing the semiconductor substrate.

15. Method for testing semiconductor substrates, as claimed in claim 14, further comprising positioning of the semiconductor substrate in another positioning method, the test tips are positioned in a plane situated parallel to the bearing surface, in relation to the semiconductor substrate, and by actuating a switch-over switch, control of the first positioning method is applied to the second positioning method.
